(19) United States
(12) Patent Application Publication
(10) Pub. No.: US 2014/0144875 A1
(43) Pub. Date: May 29, 2014

(54) Method for Manufacturing Reflective Polarizer

(71) Applicant: Jung Ku Lim, Asan-si (KR)

(72) Inventor: Jung Ku Lim, Asan-si (KR)

(73) Assignee: Dongwoo-Fine-Chem Co.ltd, Iksan-si (KR)

(21) Appl. No.: 14/125,530

(22) PCT Filed: Jan. 18, 2012
(86) PCT No.: PCT/KR2012/000435

§ 371 Date: Dec. 11, 2013

(30) Foreign Application Priority Data
Jun. 15, 2011 (KR) 10-2011-0057764

(51) Int. Cl. G02B 5/30; C23C 14/34

(52) U.S. Cl. CPC G02B 5/3058; C23C 14/34
USPC 216/24

(57) ABSTRACT

Disclosed is a method for manufacturing a reflective polarizer, the method including: coating a block copolymer composed of first and second blocks on a supporter and setting an arrangement direction of the first and second blocks by applying shear force in one direction; thermally treating the block copolymer having the set arrangement direction to allow the block copolymer to be separated and arranged into the first and second blocks in a lamellae structure; etching one of the first and second blocks to form a pattern; and forming a metal layer on the block copolymer having the pattern, so that the reflective polarizer can have a thin thickness due to a single layer of metal pattern and thus can maintain a polarization degree and a transmittance equal to or higher than those of the absorptive reflector and a large-are polarizer can be easily manufactured as a low cost.

### TECHNICAL FIELD

The present invention relates to a method for manufacturing a reflective polarizer, which can easily manufacture a large-area reflective polarizer having an excellent polarization degree and transmittance at a low cost by using a block copolymer.

### BACKGROUND ART

A polarizer means an optical device that draws a linearly polarized light having a specific vibration direction from a non-polarized light such as a natural light.

A wire grid polarizer is one kind of optical device and makes a polarized light by using a conductive wire grid. The wire grid polarizer has a polarized light separating performance higher than those of other polarizers, and thus has been used as a useful reflective polarizer in an infrared wavelength band.

This wire grid polarizer is manufactured through a plurality of processes, such as a metal depositing process on a substrate, a photoresist coating process, a photolithographic process, a photoresist developing process, a metal layer etching process, and a photoresist stripping process. In the polarizer, the pitch between grid wires and the width and height of the grid wire are important factors for determining optical characteristics thereof, but these factors are difficult to control since the plurality of processes are carried out.

Therefore, the conventional reflective polarizer such as the wire grid polarizer has disadvantages of having a low polarization degree and transmittance as compared with an absorptive polarizer.

In order to solve these disadvantages, Korean Patent Publication No. 2008-91981 discloses a double-layer structure wire grid polarizer including a light-transmissive substrate; a plurality of first conductive metal wires arranged in parallel with each other at a predetermined interval on the light-transmissive substrate; a light-transmissive intermediate layer disposed on the first conductive metal wires; and a plurality of second conductive wires arranged in parallel with each other at a predetermined interval on the intermediate layer.

Although the double-layer structure wire grid polarizer secures a polarization degree and a transmittance, which are equal to or higher than those of the absorptive polarizer, it may not be appropriate for thin film type image display devices due to a large thickness thereof. Moreover, since the above processes need to be carried out two times, the manufacturing cost thereof is high when large-area polarizers are mass-produced.

### DETAILED DESCRIPTION OF THE INVENTION

### Technical Problem

Therefore, the present invention has been made in view of the above-mentioned problems, and an aspect of the present invention is to provide a method for manufacturing a reflective polarizer capable of easily manufacturing a thin reflective polarizer by using a block copolymer without processes that are complicated or cost much.

Another aspect of the present invention is to provide a method for manufacturing a reflective polarizer capable of maintaining the polarization degree and the transmittance equal to or higher than those of an absorptive polarizer.

### Technical Solution

The present inventors found that a polarizer can be easily manufactured by using an arrangement of respective blocks of a lamella structure and processes of etching of the blocks, metal deposition, and the like, the lamella structure being formed by self-assembling of a block copolymer composed of a first block and a second block, and then completed the present invention.

In accordance with an aspect of the present invention, there is provided a method for manufacturing a reflective polarizer, the method including: coating a block copolymer composed of first and second blocks on a supporter and setting an arrangement direction of the first and second blocks by applying shear force in one direction; thermally treating the block copolymer having the set arrangement direction to allow the block copolymer to be separated and arranged into the first and second blocks in a lamellae structure; etching one of the first and second blocks to form a pattern; and forming a metal layer on the block copolymer having the pattern.

Here, in the setting of the arrangement direction, a shear plate may be contacted with an upper surface of a coating of the block copolymer.

The block copolymer may be poly(styrene-b-methylmethacrylate), poly(styrene-b-ethylene), poly(styrene-b-butadiene), poly(styrene-b-isoprene), poly(styrene-b-ethylenepropylene), poly(styrene-b-ethyleneoxide), poly(styrene-b-ferrocenyldimethylsilane), poly(styrene-b-(2-vinylpyridine)), poly(styrene-b-(4-vinylpyridine)), or poly(styrene-b-dimethylsiloxane).

The thermally treating of the block copolymer may be conducted at a temperature equal to or higher than a glass transition temperature of the block copolymer or lower than a temperature at which the block copolymer is not thermally decomposed.

The etching may be conducted such that a height difference between the first block and the second block is not smaller than ½ a height of the first block.

The metal film may be formed by sputtering deposition.

The metal film may be formed of a single metal selected from the group consisting of nickel, aluminum, silver, gold, platinum, chrome, and copper, or an alloy thereof.

### Advantageous Effects

As set forth above, according to the present invention, the large-area reflective polarizer can be easily manufactured at a low cost by using self-assembling characteristics of the block copolymer, etching thereof, and the like.

Further, according to the present invention, the large area can be promptly made through easy processes as compared with the double-layer structure wire grid polarizer manufactured by exposing and etching processes using a pattern mask in order to achieve a polarization degree similar to that of the conventional absorptive polarizer, so that the method of the present invention is suitable for mass production of polarizers.

Further, the reflective polarizer manufactured according to the present invention has a single layer of metal pattern, and thus can have a thin thickness and maintain a polarization degree and a transmittance equal to or higher than those of the absorptive reflector.

### BRIEF DESCRIPTION OF THE DRAWINGS

FIGS. 1A to 1E are perspective views schematically illustrating a method for manufacturing a reflective polarizer according to an embodiment of the present invention; and,

FIGS. 2A and 2B are cross-sectional views of a reflective polarizer manufactured according to the present invention.

### MODE FOR CARRYING OUT THE INVENTION

The present invention is directed to a method for manufacturing a reflective polarizer capable of easily manufacturing a large-area reflective polarizer having an excellent polarization degree and transmittance at a low cost, by using a block copolymer.

The reflective polarizer of the present invention uses phase separation due to self-assembling of the block copolymer, and thus is less constrained by the area as compared with the reflective polarizer in which grid wires are disposed at a predetermined interval through an etching process employing the conventional pattern mask, so that the reflective polarizer of the present invention can be manufactured to have a large area. In addition, the reflective polarizer of the present invention can be manufactured at a relatively low cost since a high-priced large-area pattern exposing method is not employed.

A method for manufacturing the reflective polarizer according to the present invention includes: coating a block copolymer composed of first and second blocks on a supporter and setting an arrangement direction of the first and second blocks by applying shear force in one direction; thermally treating the block copolymer having the set arrangement direction to separate and arrange the first and second blocks in a lamellae structure; etching one of the first and second blocks to form a pattern; and forming a metal layer on the block copolymer having the pattern.

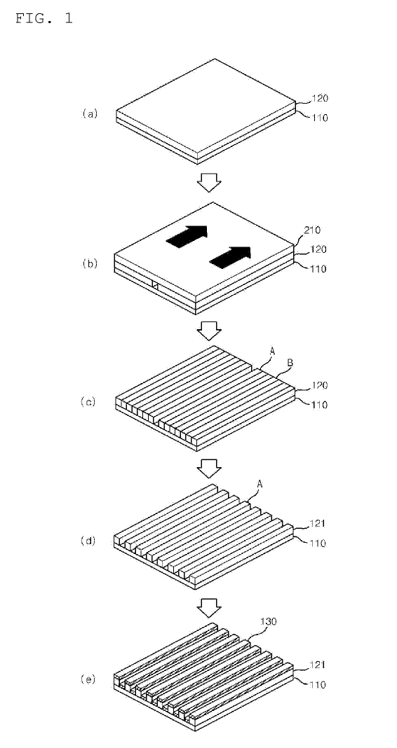

Hereinafter, a method for manufacturing a reflective polarizer according to an embodiment of the present invention will be set forth by steps with reference to FIGS. 1A to 1E.

A block copolymer composed of first and second blocks is coated on a supporter 110 to form a coating of the block copolymer 120 (FIG. 1A).

The supporter may support the block copolymer to induce self-assembling of the block copolymer, and the kind thereof is not particularly limited as long as it can have light transmittance. Examples thereof may be a transparent glass, a polymer film, and the like.

After the block copolymer is coated, a shear stress is applied thereto in one direction to set an arrangement direction of the first block and the second blocks (FIG. 1B).

The method of applying the shear stress is not particularly limited as long as it allows the shear stress to be applied in one direction. For example, the shear stress may be applied while a shear plate 210 is laid on the coating, and here, a roll may be used.

The shear stress needs to be applied in only one direction to obtain a regular pattern arrangement. Specifically, it is preferable that a predetermined magnitude of shear stress is applied in any one of a vertical direction and a horizontal direction with respect to the long axis of the substrate. The magnitude of the shear stress applied is such that the shear plate can move to several nanometers to several centimeters.

Then, the block copolymer coated on the supporter is thermally treated to induce self-assembling thereof, such that the block copolymer is divided and arranged into the first block and the second block in a lamellae structure (FIG. 1C). Due to the above procedure, a block copolymer coating film 121 having the lamellae structure is formed.

Herein, the first block and the second block each include a block consisting of repetition units of the same polymer as well as repetition units of polymers having similar properties. That is, the block copolymer of the present invention may include a double-, triple-, or multiple-block copolymer, and is not particularly limited as long as properties thereof can be divided and arranged into two or more.

The self-assembling of the block copolymer occurs in a manner that a lamellae domain of one block of the first block and the second block constituting the block copolymer and a lamellae domain of the other domain thereof are grown at different sites, respectively.

The block copolymer may be a copolymer in which a block of polystyrene and a block of a polymer other than polystyrene are covalently linked to each other. Specific examples thereof may be poly(styrene-b-methylmethacrylate)(PS-b-PMMA), poly(styrene-b-ethylene)(PS-b-PE), poly(styrene-b-butadiene)(Ps-b-PB), poly(styrene-b-isoprene)(Ps-b-PI), poly(styrene-b-ethylenepropylene) (PS-b-PEP), poly(styrene-b-ethyleneoxide)(PS-b-PEO), poly(styrene-b-ferrocenyl dimethylsilane)(PS-b-PFS), poly(styrene-b-(2-vinylpyridine))(PS-b-P2VP), poly(styrene-b-(4-vinylpyridine))(PS-b-P4VP), and poly(styrene-b-dimethylsiloxane)(PS-b-PDMS).

The kind of block copolymer is not limited thereto, and any block copolymer that can form the lamellae structure may be used. For example, poly(styrene-b-methylmethacrylate) is obtained by polymerizing a first block of polystyrene and a second block of polymethylcrylate.

The thermal treatment conditions for self-assembling of the block copolymer are set to a temperature range from not lower than a glass transition temperature of the block copolymer, at which the block copolymer has fluidity, to not higher than a temperature, at which the block copolymer is not thermally decomposed. For example, poly(styrene-b-methylcrylate) may be self-assembled at 100□ or higher, but it takes a long time for poly(styrene-b-methylcrylate) to complete the self-assembling thereof at a low temperature. Therefore, the thermal treatment may be conducted at about 250□ in a high-vacuum atmosphere excluding oxygen. In this case, the flow of molecules is smooth and thus regular self-assembling can be completed in a short time.

Before the thermal treatment, the first blocks and the second blocks of the copolymer are disorderedly distributed without forming particular patterns. As the thermal treatment proceeds, movement of molecules occurs and the same components form a predetermined pattern.

That is, the first blocks gather to form a predetermined pattern and the second blocks gather to form a predetermined structure. Depending on a relative ratio (volume ratio) of the two kinds of polymer blocks, various nanostructures, for example, a sphere, a cylinder, a gyroid, and a lamellae are formed. In the block copolymer of the present invention, the lamellae structure is stable, and thus the first blocks and the second blocks gather, respectively, to form a lamellae structure. Here, the volume ratio of two kinds of polymer blocks is 50:50.

In addition, the thickness and height of each of the first block and the second block in the lamellae structure may be controlled depending on the molecular weight of each block. For example, in poly(styrene-b-methylmethacrylate), a first block of polystyrene and a second block of polymethylmethacrylate each have a molecular weight of 52,000 kg/mol, and thus the first block and the second block have the same thickness and height.

Then, any one of the first block and the second block is etched to form a pattern (FIG. 1D). The first block or the second block may be removed by wet etching or dry etching.

For example, in the case where the block copolymer is poly(styrene-b-methylmethacrylate), only a polymethylmethacrylate block may be removed by conducting, after ultraviolet ozone treatment (UVO), wet etching with an acetic acid solution or oxygen plasma etching as dry etching. In addition, the distortions of the lamellae structure can be minimized by dry etching rather than wet etching.

Here, the etching may be conducted such that a height difference between the etched first and second blocks is not smaller than ½ the height of the first block. The height difference between the first block and the second block is preferably 50 cm or larger, in order to allow the polarizer of the present invention to easily function as a polarizer.

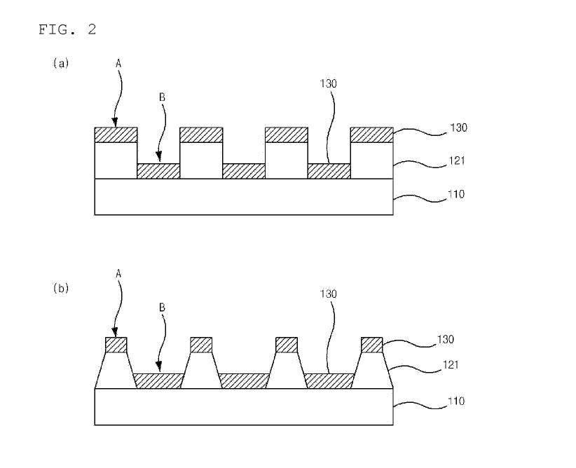

In addition, the angle of the etched block with respect to the supporter may be adjusted to control the polarization degree and transmittance by wavelengths. For example, the etched block and the supporter may form a right angle (FIG. 2A) or an obtuse angle (FIG. 2B).

In addition, the polarization degree and transmittance by wavelengths may be controlled according to the shape of the etched block, the period of blocks, the volume of the block, or the like.

Therefore, it is preferable to control the polarization degree and transmittance in appropriate consideration of the above matters in order to exhibit desired polarization characteristics.

Then, a metal film 130 is formed on the block copolymer layer having the pattern (FIG. 1E). The metal film is formed by metal sputtering deposition, and covers the entire surface of the block copolymer subjected to etching.

The metal film may be formed of a single metal selected from the group consisting of nickel, aluminum, silver, gold, platinum, chrome, and copper, or an alloy thereof. The alloy may be one in which the single metal is contained at a predetermined proportion, or one in which the single metal is mainly contained and small amounts of other metals are contained.

An example thereof may be nichrome, specifically, a nickel-chrome alloy or a nickel-chrome-iron alloy. In addition, an example thereof may be inconel, specifically, an alloy in which nickel is mainly contained and chrome, iron, titanium, aluminum, manganese, and silicon are also contained.

The metal film may be embodied through sputtering, and the thickness thereof is not particularly limited as long as the metal film can function as a reflective polarizer. Specifically, the thickness thereof may be 0.1 to 300 nm.

According to the present invention, the reflective polarizer is manufactured by forming the metal film 130 on the block copolymer, which has the pattern formed by etching, as shown in FIG. 1E. Specifically, in the reflective polarizer, portions in which the metal film is formed on the first block that is not etched and portions in which the metal film is formed on the second block that is etched are alternately arranged.

Hereinafter, preferable examples are provided to help understanding of the present invention, but the following examples are provided merely to illustrate the present invention and not to restrict the accompanying claims. It is obvious to those skilled in the art that various changes and modifications can be made within the scope and technical range of the present invention and these changes and modification are included in the accompanying claims.

### Example 1

A block copolymer (PS-b-PMMA) was spin-coated on one surface of a transparent supporter (Corning Company, Glass). The block copolymer includes a first block of polystyrene and a second block of polymethylmethacrylate, each having a molecular weight of 52,000 kg/mol, the volume ratio of the first block and the second block being 50:50.

After that, a shear plate was placed on the coating, and then a shear force was applied to the supporter such that the same force was uniformly applied in a vertical direction with respect to the long axis of the supporter.

After that, the supporter coated with the block copolymer was thermally treated at 250□ in a high-vacuum atmosphere for 48 hours, to thereby induce self-assembling of PS-b-PMMA, so that the block copolymer was divided and arranged into the first block and the second block in a lamellae structure.

After that, only the second block of polymethylmethacrylate was completely removed by using oxygen plasma etching, to form a pattern. The etching was conducted such that the transparent film support was at a right angle to the second block. Here, the height of the first block was 100 nm.

An aluminum film was formed on the block copolymer having the pattern by metal sputtering deposition, with the result that a reflective polarizer was manufactured.

### Example 2

A reflective polarizer was manufactured by the same method as Example 1 except that the height difference between the first block and the second block was 60 nm.

### Comparative Example 1

### Absorptive Polarizer

An absorptive polarizer made of a polyvinyl alcohol-based resin and having iodine adsorbed and aligned therein (Sumitomo Chemical Company, polarizer for an LCD TV).

### Comparative Example 2

### Reflective Polarizer

A wire grid polarizer having a structure in which a plurality of conductive metal wires are arranged in parallel with each other at a predetermined interval on a transparent substrate (Edmund Company, Model: 47-102).

### Comparative Example 3

### Double-Layer Structure Reflective Polarizer

A first metal layer of aluminum was deposited on a light-transmissive substrate. A first grid pattern was transferred onto the first metal layer, the first grid pattern having grid elements arranged in parallel with each other at a predetermined interval. After that, the first metal layer was etched by using the first grid pattern as a mask until the light-transmissive substrate was exposed, to thereby form first metal wires.

The etched first metal layer was filled with a light-transmissive dielectric material, and then an intermediate layer was formed by using spin coating. A second metal layer of aluminum was deposited on the intermediate layer, and then a second grid pattern was transferred onto the intermediate layer, the second grid pattern having grid elements arranged in parallel with each other at a predetermined interval. The second metal layer was etched by using the second grid pattern as a mask until the intermediate layer was exposed, to thereby form second metal wires, with the result that a double-layer structure reflective polarizer was manufactured. Here, the second metal wires each are arranged between the first metal wires.

### Comparative Example 4

### Metal Film formed on Etched Portion

A reflective polarizer was manufactured by the same method as Example 1 except that an aluminum film was formed on a second block-etched portion of the block copolymer having the pattern by metal sputtering deposition.

### Experimental Example

Properties of the polarizers manufactured in the example and comparative examples were measured by the following methods, and the results thereof were tabulated in Table 1.

1. Polarization Degree and Transmittance

An adhesive composition was coated on both surfaces of the manufactured polarizer such that a dry film has a thickness of 0.1 μm, and then a saponified acetylcellulose-based film (30 cm×20 cm) was bonded thereto, with the result that a polarizing plate was manufactured.

The thus manufactured polarizing plate was cut into a size of 4 cm×4 cm, followed by measurement using an ultraviolet-visible spectrometer (V-7100, manufactured by JASCO Company). The polarization degree is defined by equation 1 below.

Polarization degree(P)=[(T₁−T₂)/(T₁+T₂)]^{1/2} [Equation 1]

(where, T₁ is the parallel transmittance obtained when a pair of polarizing plates are disposed such that absorption axes thereof are parallel with each other, and T₂ is the orthogonal transmittance obtained when a pair of polarizing plates are disposed such that absorption axes thereof are orthogonal to each other).

2. Thickness

The thickness of the manufactured polarizer was measured by using an electron microscope.

TABLE 1

| | Polarization | Transmittance | Thickness |
|---|---|---|---|
| | degree (%) | (%) | (nm) |
| Example 1 | 99.982 | 40 | 200 |
| Example 2 | 99.97 | 42 | 160 |
| Comparative example 1 | 99.995 | 42 | 120 |
| (absorptive polarizer) | | | |
| Comparative example 2 | 89.9 | 73.8 | 500 |
| (reflective polarizer) | | | |
| Comparative example 3 | 99.9 | 37 | 400 |
| (double-layer structure | | | |
| polarizer) | | | |
| Comparative example 4 | 98.71 | 70 | 100 |
| (thin film formed on | | | |
| etched portion) | | | |

As shown in table 1 above, it may be confirmed that the reflective polarizer manufactured according to the present invention was thinner than the reflective polarizers of comparative examples 2 and 3, and exhibited the polarization degree and transmittance equal to or higher than those of the absorptive polarizer of comparative example 1.

It may be confirmed that the polarizer of comparative example 4, in which the thin film was formed on only the etched second block, exhibited a low polarization degree and transmittance.

While the present invention has been described with reference to the embodiment shown in the drawings, it is simply illustrative, and it will be understood by those skilled in the art that various modifications and other equivalent embodiments can be made without departing from the spirit and the scope of the present invention.

(Reference numerals)

| | |
|---|---|
| A: first block | B: second block |
| 110: supporter | |
| 120: coating of block copolymer | |
| 121: coating of block copolymer having | |
| lamellae structure | |
| 130: metal film | 210: shear plate |

1. A method for manufacturing a reflective polarizer, the method comprising:
coating a block copolymer composed of first and second blocks on a supporter and setting an arrangement direction of the first and second blocks by applying shearing force in one direction;
thermally treating the block copolymer having the set arrangement direction to allow the block copolymer to be separated and arranged into the first and second blocks in a lamellae structure;
etching one of the first and second blocks to form a pattern; and
forming a metal layer on the block copolymer having the pattern.

2. The method of claim 1, wherein in the setting of the arrangement direction, a shear plate is contacted with an upper surface of a coating of the block copolymer.

3. The method of claim 1, wherein the block copolymer is poly(styrene-b-methylmethacrylate), poly(styrene-b-ethylene), poly(styrene-b-butadiene), poly(styrene-b-isoprene), poly(styrene-b-ethylenepropylene), poly(styrene-b-ethyleneoxide), poly(styrene-b-ferrocenyldimethylsilane), poly(styrene-b-(2-vinylpyridine)), poly(styrene-b-(4-vinylpyridine)), or poly(styrene-b-dimethylsiloxane).

4. The method of claim 1, wherein the thermal treating of the block copolymer is performed at a temperature equal to or higher than a glass transition temperature of the block copolymer or lower than a temperature at which the block copolymer is not thermally decomposed.

5. The method of claim 1, wherein the etching is performed such that a height difference between the first block and the second block is not smaller than ½ a height of the first block.

6. The method of claim 1, wherein the metal film is formed by sputtering deposition.

7. The method of claim 6, wherein the metal film is formed of a single metal selected from the group consisting of nickel, aluminum, silver, gold, platinum, chrome, and copper, or an alloy thereof.
